(19) United States
(12) Patent Application Publication
(10) Pub. No.: US 2008/0092952 A1
(43) Pub. Date: Apr. 24, 2008

(54) INTEGRATED AMORPHOUS SILICON DOUBLE-JUNCTION SOLAR CELL CURTAIN WALL AND METHODS FOR MANUFACTURING AND USING THE SAME

(76) Inventors: Wukui CHEN, Shenzhen (CN); Ying REN, Shenzhen (CN); Xiaoquan LEI, Shenzhen (CN)

Correspondence Address: MATTHIAS SCHOLL, 14781 MEMORIAL DRIVE, SUITE 1319, HOUSTON, TX, 77079, US

(21) Appl. No.: 11/876,828

(22) Filed: Oct. 23, 2007

(30) Foreign Application Priority Data
Oct. 23, 2006 (CN) 200610063236.5

(51) Int. Cl. H01L 31/00

(52) U.S. Cl. 136/258; 438/66; 257/E33.001

(57) ABSTRACT

Provided is an integrated amorphous silicon double-junction solar cell curtain wall, comprising a plurality of photovoltaic curtain wall plates, each of which being encapsulated by a double-junction amorphous silicon solar cell chip with a glass substrate, a glass plate, a glue film, a junction box, a lead and a frame; and an electric control unit having a controller; wherein an output of the photovoltaic curtain wall plate is connected to the controller of the electric control unit. A double-junction double-layer solar cell top cell film layer and a bottom cell film layer are disposed on a glass substrate of the cell chip, each of the top cell film layer and the bottom cell film layer comprising a P-layer, an I-layer, and an N-layer; an I-layer of the top cell film layer is amorphous silicon; and an I-layer of the bottom cell film layer is amorphous silicon or amorphous germanium-silicon. The invention solves problems of solar power generation and application, and features with good energy saving effect, safety, reliability and wide applications. Generated energy of the cell chip per square meter is 30-60 W, photoelectric conversion efficiency is 5-7%, an attenuation rate is 20-30%, output efficiency after conversion is approximately 80%. The invention is usable for solar power generation and wall decoration of buildings.

### CROSS-REFERENCE TO RELATED APPLICATIONS

This application claims priority to Chinese Patent Application No. 200610063236.5 filed on Oct. 23, 2006, the contents of which are incorporated herein by reference.

### BACKGROUND OF THE INVENTION

1. Field of the Invention

The invention relates to a solar cell curtain wall, and particularly to an integrated amorphous silicon double-junction solar cell curtain wall and methods for manufacturing and using the same.

2. Description of the Related Art

Renewable and eco-friendly energy sources have been developed during the past few decades, and include solar cells made of monocrystalline silicon, polycrystalline silicon, amorphous silicon, gallium arsenide, nanometer titanium dioxide, and so on.

Conventionally, a glass curtain wall of an existent solar cell employs inlaying structure, in which a single-decked solar cell board is disposed between two glass surfaces. China patent number CN1702251A discloses a laminated rubber glass for an amorphous silicon solar cell, and China patent number CN2498243A discloses a glass for a photoelectric curtain wall. However, problems with traditional solar cells include the complexity of the inlaying structure, relatively heavy glass curtain wall, and lackluster appearance.

### SUMMARY OF THE INVENTION

In view of the above-described problems, it is one objective of the invention to provide an integrated amorphous silicon double-junction solar cell curtain wall and methods for manufacturing and using the same.

To achieve the above objectives, in accordance with one embodiment of the invention, provided is an integrated amorphous silicon double-junction solar cell curtain wall, comprising a plurality of photovoltaic curtain wall plates and an electric control unit having a controller; wherein the photovoltaic curtain wall plate is encapsulated by a double-junction amorphous silicon solar cell chip with a glass substrate, a tempered glass plate, a glue film, a junction box, a lead, and a frame; the plurality of photovoltaic curtain wall plates are connected to form a frame-type integrated wall; an electric output of the photovoltaic curtain wall plate is connected to a controller of an electric control unit; and the controller is connected to a power distributing cabinet via a network inverter.

In certain classes of this embodiment, the glass substrate comprises one of tin oxide, indium tin oxide, or aluminum doped zinc oxide; a tandem solar cell film layer and a back electrode are disposed on the glass substrate; the tandem solar cell film layer comprises a top cell film layer and a bottom cell film layer; each of the top cell film layer and the bottom cell film layer comprises a P-layer, an I-layer, and an N-layer; an I-layer of the top cell film layer is amorphous silicon; and an I-layer of the bottom cell film layer is amorphous silicon or amorphous germanium-silicon.

In certain classes of this embodiment, a lightning protection system is disposed between the output of the photovoltaic curtain wall plate and the controller.

In certain classes of this embodiment, the power distributing cabinet is connected to an urban power network via an input electric meter and an output electric meter.

In accordance with another embodiment of the invention, provided is a method for manufacturing an integrated amorphous silicon double-junction solar cell curtain wall of claim 1, comprising encapsulating a photovoltaic curtain wall plate; connecting a plurality of photovoltaic curtain wall plates to form an integrated wall via a frame-type structure; and encapsulating an electric control unit; wherein a process of manufacturing a double-junction amorphous silicon solar cell chip comprises:

(1) choosing a glass substrate containing a tin oxide layer of 5000 Å-8000 Å in thickness, cleaning the glass substrate, and rearranging the glass substrate;

(2) segmenting film layers on the glass substrate via laser ablation, and producing a cathode of the solar cell chip;

(3) accommodating the glass substrate with a fixture deposited with p-layers, i-layers, and n-layers, heating the glass substrate to 180° C.-250° C. in a preheating furnace, vacuum evacuating a deposit chamber of a plasma enhanced chemical vapor deposition device (PECVD) to a pressure of between 5.0×10⁻³ Pa and 9.0×10⁻³ Pa, introducing residual nitrogen gas with a purity above 99%, and placing the glass substrate into the PECVD;

(4) introducing a mixture of gasses comprising SiH₄, CH₄ and B₂H₆ (volume ratio 1:0.8-1.2:0.008-0.012), performing glow discharge with a radio frequency of 10-60 MHz and a discharge power of 80 W-200 W, under a deposition temperature of 160-300° C. and a pressure of 40-1000 Pa, and depositing a top cell P-film layer, a thickness of the deposited film being 80 Å-200 Å;

(5) introducing a mixture of gasses comprising SiH₄ and H₂ (volume ratio 1: 1-10) after vacuum evacuating the deposit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a top cell I-film layer on the top cell P-film layer, a thickness of the deposited film being 500 Å-1000 Å;

(6) introducing a mixture of gasses comprising SiH₄ and PH₃ (volume ratio 1:0.008-0.012) after vacuum evacuating the deposit chamber of the PECVD to a pressure of between 50×10⁻³ Pa and 9.0×10⁻³, performing glow discharge with a radio frequency of 10-60 MHz and a discharge power of 150 W-250 W, under a deposition temperature of 160-300° C. and a pressure of 40-1000 Pa, and depositing a top cell N-film layer on the top cell I-film layer, a thickness of the deposited film being 100 Å-300 Å; and

(7) introducing a mixture of gasses comprising SiH₄, CH₄ and B₂H₆ (volume ratio 1:0.8-1.2:0.008-0.012) after vacuum evacuating the deposit chamber of the PECVD to a pressure of between 5.0×10⁻³ Pa and 9.0×10⁻³, performing glow discharge with a radio frequency of 10-60 MHz and a discharge power of 80 W-200 W, under a deposition temperature of 160-300° C. and a pressure of 40-1000 Pa, and depositing a bottom cell P-film layer on the top cell N-film layer, a thickness of the deposited film being 80 Å-200 Å.

(8) A. introducing a mixture of gasses comprising SiH4 and H2 at a volume ratio of 1:0.7-1.3 after vacuum evacuating the deposit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a bottom cell I-film layer on the bottom cell P-film layer, a thickness of the deposited film being 200 Å-1000 Å.

B. introducing a mixture of gasses comprising SiH4, GeH4 and H2 at a volume ratio of 1:0.4-0.6:1-5 after vacuum evacuating the deposit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a bottom cell amorphous germanium silicon I-film layer on the bottom cell P-film layer, a thickness of the deposited film being 1000 Å-2500 Å.

(9) introducing a mixture of gasses comprising SiH4 and PH3 at a volume ratio of 1:0.008-0.012 after vacuum evacuating the deposit chamber of the PECVD to a pressure of between 5.0×10⁻³ Pa and 9.0×10⁻³, performing glow discharge with a radio frequency of 10-60 MHz and a discharge power of 150 W-250 W, under a deposition temperature of 160-300° C. and a pressure of 80-200 Pa, and depositing a bottom cell N-film layer on the bottom cell I-film layer, so as to form a dual P-I-N junction film layer, a thickness of the deposited film being 300 Å-500 Å;

(10) segmenting the dual P-I-N junction film layer on the glass substrate via laser ablation, so as to produce a series of electrodes;

(11) placing the glass substrate into the deposit chamber of the PECVD, and depositing back electrode film layer made of aluminum, a thickness of the film being 5000 Å-8000 Å;

(12) segmenting the back electrode film layer via laser ablation, so as to produce a series of back electrodes of the solar cell chip; and

(13) welding electrode wires of the positive electrode and the back electrode.

In certain classes of this embodiment, a transmittance of the glass substrate is 90%-98%, and an iron content of the glass substrate is 60 ppm-80 ppm, and the glass substrate has high light transmittance and low iron content, which makes it possible for more sunshine to enter the amorphous silicon solar cell, and thus after photovoltaic effect, more power can be obtained. A thickness of the glass substrate ranges from 2 mm to 20 mm. For example, a glass with the following dimension is preferably employed: a length of 915 mm-1830 mm, a width of 305 mm-615 mm, and a height of 3 mm-5 mm.

A process for producing a photovoltaic curtain wall plate is as follows: the amorphous silicon double-junction solar cell chip referred above is laminated and adhered to a new-bought tempered glass plate with a same size altogether, and a rectangular frame made of an aluminum alloy profile is inlayed on four sides thereof, electrode wires of a positive electrode and a back electrode pass through holes on the tempered glass plate, a terminal box is fixed thereon via weather proofing silicone sealant, and an outlet line is connected thereto. Thus, the “photovoltaic curtain wall plate” of the amorphous silicon double-junction solar cell curtain wall is formed.

One to two holes for passing through electrode wires may be produced on the tempered glass plate. A thickness of the tempered glass plate ranges from 5 mm to 20 mm.

Aluminum alloy profiles and aluminum corner connectors for producing a frame of the photovoltaic curtain wall plate may be designed freely as required. The aluminum alloy profiles and the aluminum corner connectors produces a frame of a glass of the photovoltaic curtain wall plate, so as to form a complete and standard module, and then the module is fixed to a post or a beam of a building via M6-type stainless steel screws.

The outlet lines of the photovoltaic curtain wall plate may be serially connected into several groups, and the groups may be further parallel connected to form a photovoltaic curtain wall array according to actual requirements for designing the curtain wall. Based on a requirement for voltage output, the entire photovoltaic curtain wall may be designed to have one or more outputs, and to be connected with an electric control unit of the curtain wall. After debugging, assembly of the integrated amorphous silicon double-junction solar cell chip glass curtain wall is completed.

In certain classes of this embodiment, the integrated amorphous silicon double-junction solar cell curtain wall is usable for solar power generation and wall decoration of buildings.

Advantages of the invention comprise: 1) the invention provides clean energy; 2) power-savings; 3) good performance with a photoelectric conversion efficiency of 5-7%, an attenuation rate of 20-30%, output efficiency after conversion of approximately 80%, and generated energy generated by the integrated amorphous silicon double-junction solar cell chip per square meter is 30-50 W; 4) safety and reliability; and 5) wide applicability.

### BRIEF DESCRIPTION OF THE DRAWINGS

FIG. 1 is a diagram of an integrated amorphous silicon double-junction solar cell curtain wall according to one embodiment of the invention;

FIG. 2 is a schematic diagram of a double-junction solar cell chip according to one embodiment of the invention;

FIG. 3 is a schematic diagram of an A-type double-junction amorphous silicon solar cell curtain wall according to one embodiment of the invention;

FIG. 4 is a schematic diagram of a B-type double-junction amorphous silicon solar cell curtain wall according to one embodiment of the invention;

FIG. 5 is an encapsulation diagram of an A-type double-junction amorphous silicon solar cell curtain wall according to one embodiment of the invention;

FIG. 6 is an encapsulation diagram of an B-type double-junction amorphous silicon solar cell curtain wall according to one embodiment of the invention;

FIG. 7 is a cross-sectional view of a frame of a photovoltaic curtain wall plate according to one embodiment of the invention;

FIG. 8 is a cross-sectional view of a frame of a photovoltaic curtain wall plate according to another embodiment of the invention;

FIG. 9 illustrates connection between a photovoltaic curtain wall plate and a post/beam of a building according to one embodiment of the invention (a type of fixing a center of a curtain wall);

FIG. 10 illustrates connection between a photovoltaic curtain wall plate and a post/beam of a building according to one embodiment of the invention, in which

FIG. 10-1 illustrates a horizontal contact;

FIG. 10-2 illustrates a vertical leftover contact;

FIG. 10-3 illustrates a horizontal leftover contact;

FIGS. 11-1 and 11-2 illustrates connection between a photovoltaic curtain wall plate and a post/beam of a building according to another embodiment of the invention;

FIG. 12 is an encapsulation diagram of an aluminum corner connection of a photovoltaic curtain wall plate;

FIG. 13 is a diagram illustrating a principle of stand-alone power generation by the integrated amorphous silicon double-junction solar cell curtain wall according to one embodiment of the invention; and

FIG. 14 is a diagram illustrating a principle of interconnected power generation by the integrated amorphous silicon double-junction solar cell curtain wall according to one embodiment of the invention.

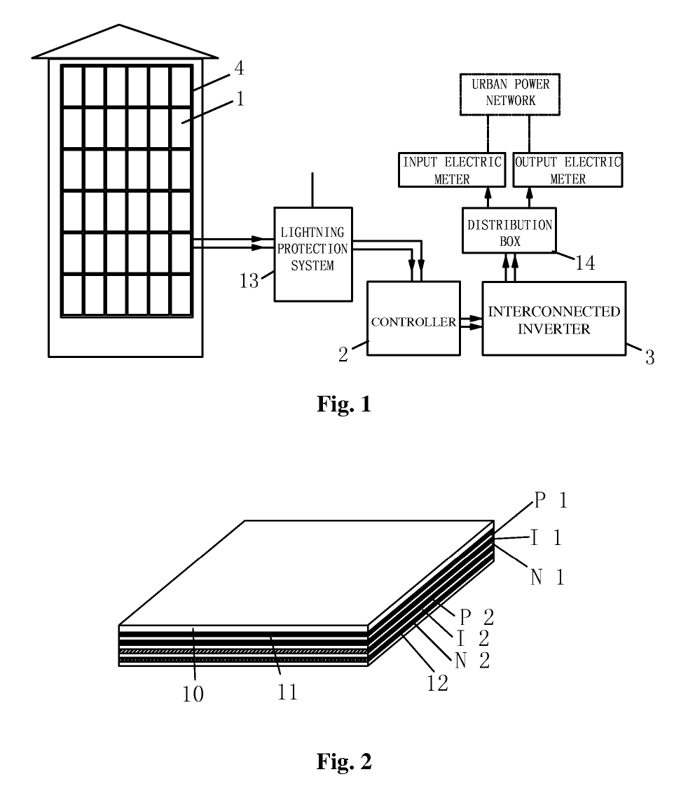

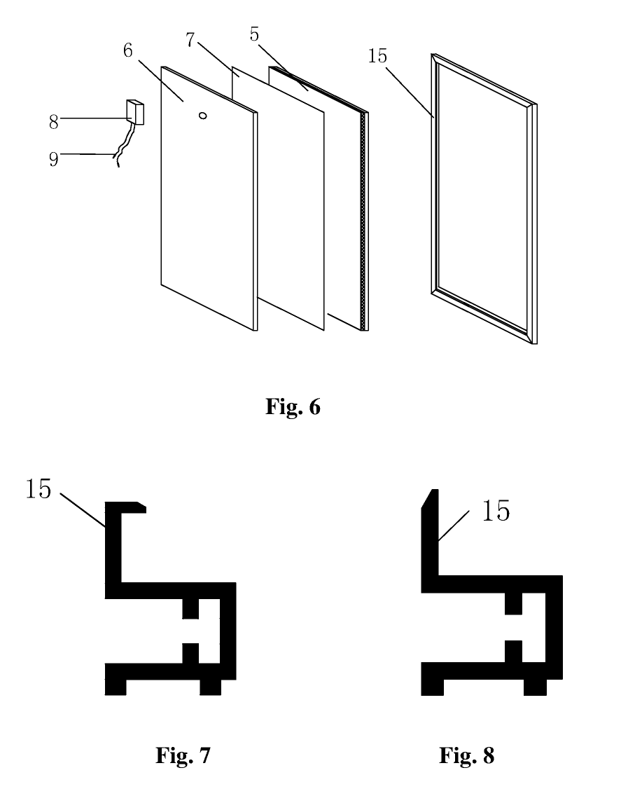

In FIGS. 1-6, 1 is a photovoltaic curtain wall plate, 2 is a controller, 3 is a network inverter, 4 is a frame of a building structure, 5 is a double-junction amorphous silicon solar cell chip, 6 is a tempered glass plate, 7 is a glue film, 8 is a junction box, 9 is a lead, 10 is a glass substrate, 11 is a tin oxide conductive film layer, P1 is a top cell P-film layer, 11 is a top cell I-film layer, N1 is a top cell N-film layer, P2 is a bottom cell P-film layer, 12 is a bottom cell I-film layer, N2 is a bottom cell N-film layer, 12 is an aluminum film layer of a back electrode, 13 is a lightning protection system, 14 is a power distributing cabinet, and 15 is a frame.

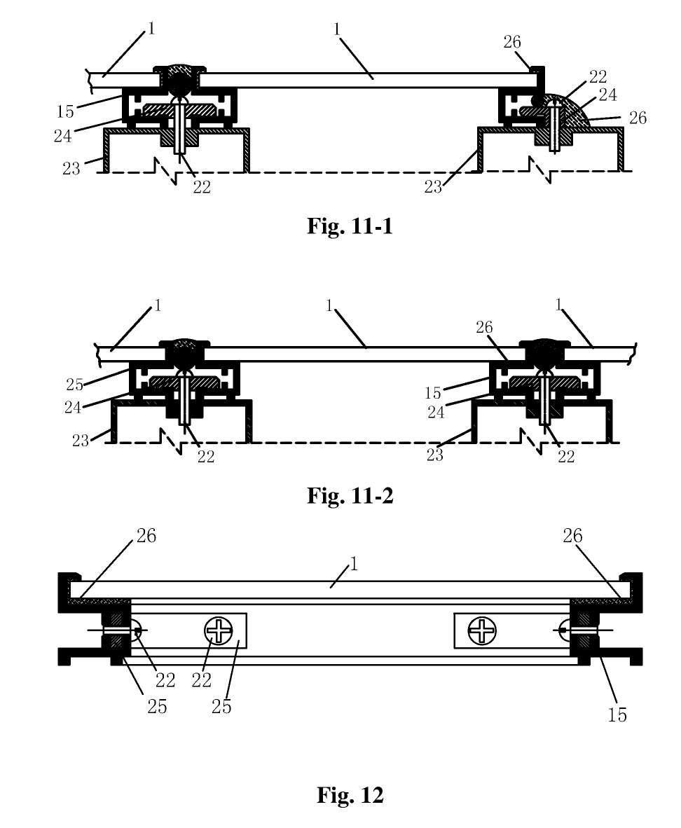

In FIGS. 7-12, 21 is a beam, 22 is a screw, 23 is a post, 24 is an aluminum press piece, 25 is an aluminum corner connector, and 26 is a silicone sealant.

In FIGS. 13 and 14, 3-1 is a standalone inverter, 16 is a battery group, 17 is an input electric meter, and 18 is an output electric meter.

As shown in FIGS. 1, 3 and 4, an integrated amorphous silicon double-junction solar cell curtain wall comprises a plurality of photovoltaic curtain wall plates 1 and an electric control unit having a controller 2. The photovoltaic curtain wall plate 1 is encapsulated by a double-junction amorphous silicon solar cell chip 5 with a glass substrate 10, a glass plate 6, a glue film 7, a junction box 8, a lead 9 and a frame 15. The plurality of photovoltaic curtain wall plates 1 is fixed on a beam 4 to form a photovoltaic curtain wall array. An electric output of the photovoltaic curtain wall plate 1 is connected to a controller 2, and the controller is connected to the power distributing cabinet 14 via an inverter 3. Meanwhile, a lightning protection system 13 is disposed between the electric output of the photovoltaic curtain wall plate 1 and the controller 2.

As shown in FIG. 2, a transparent conductive layer 11, a top cell P-film layer P1, a top cell I-film layer 11, a top cell N-film layer N1, a bottom cell P-film layer P2, a bottom cell I-film layer 12, a bottom cell N-film layer N2, an aluminum film layer 12 are sequentially disposed under the substrate 10. The top cell I-film layer 11 is amorphous silicon, and the bottom cell I-film layer 12 is amorphous silicon, or amorphous germanium-silicon.

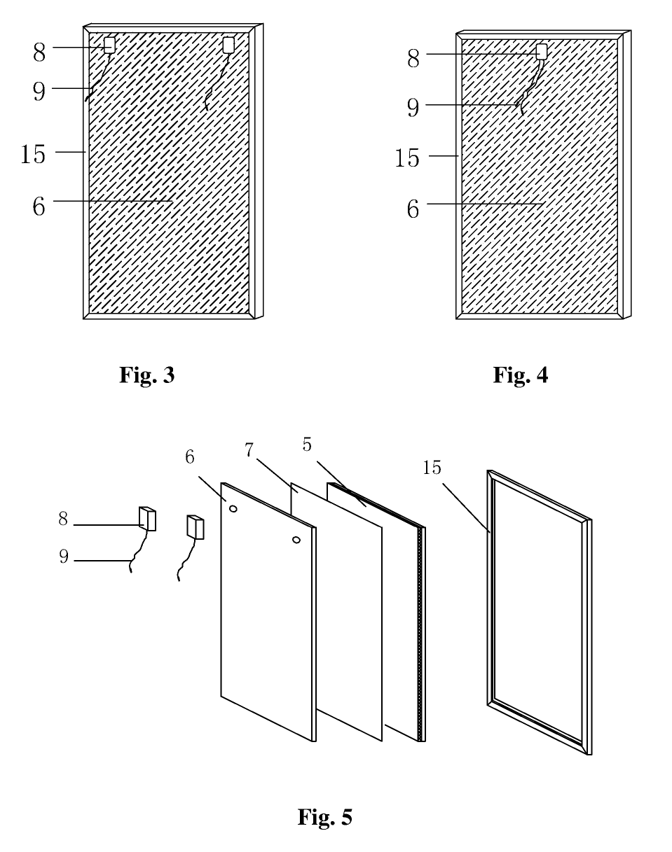

Referring to FIGS. 3 to 6, there are two types of double-junction amorphous silicon solar cell curtain walls: the A-type and the B-type. The differences between these two types are the number and position of extraction apertures on the junction boxes 8, the leads 9 and the glass plates 6, and the number and position of the junction boxes 8 and the leads 9.

Referring to FIGS. 7 and 8, frames for producing different photovoltaic curtain wall plates may be different.

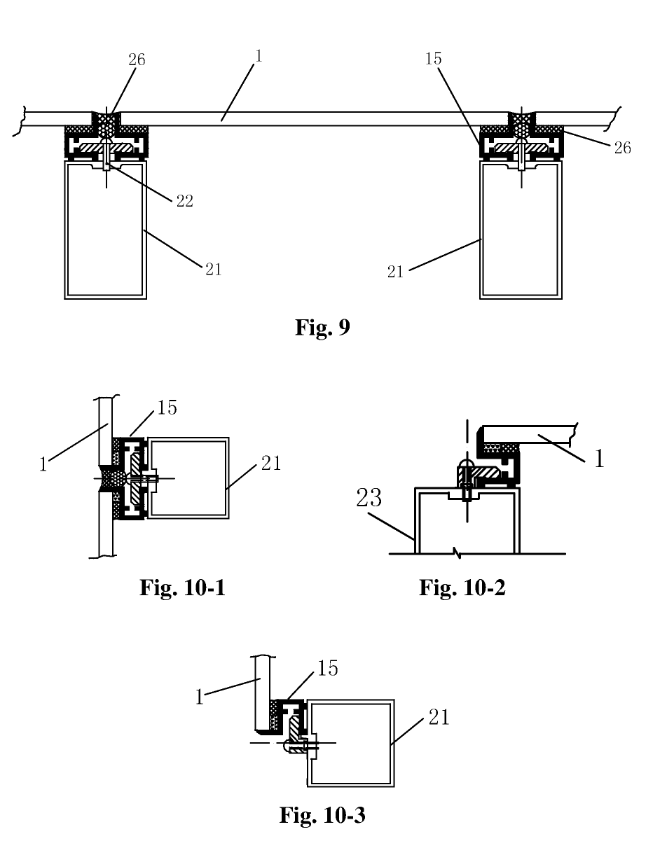

FIGS. 9-12 are detailed installation diagrams of the invention, and will be described in detail in the following embodiments.

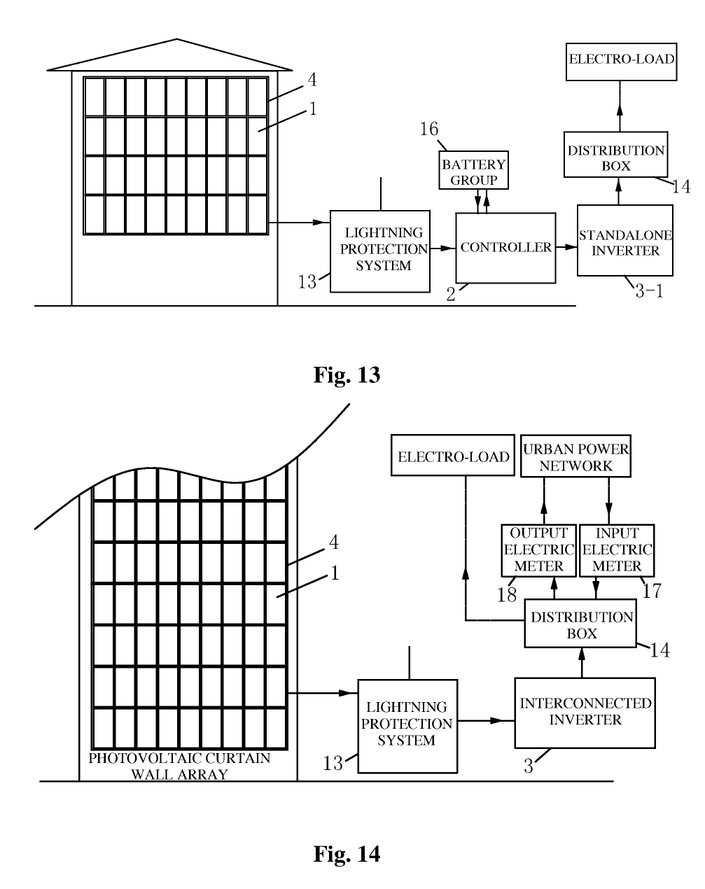

FIGS. 13 and 14 are standalone/interconnected power generation principle, and will be explained in detail in embodiment 3.

### DETAILED DESCRIPTION OF THE INVENTION

Explanation of the invention will be given below by way of detailed embodiments.

### Embodiment 1

### Manufacturing a Solar Cell Chip Comprises

### Example 1-1

(1) choosing a glass substrate containing a tin oxide layer of 5000 Å in thickness, and cleaning and rearranging the glass substrate, in this embodiment, the glass substrate is a PV-TCO made by AFG Industries, Inc., USA, with a length of 915 mm, a width of 480 mm, a height of 3.2 mm, a transmittance of 90%, and iron content of 60 ppm;

(2) segmenting film layers on the glass substrate via laser ablation, and producing a cathode of the solar cell chip;

(3) accommodating the glass substrate with a fixture deposited with P-, I- and N-film layers, heating the glass substrate to 210° C. in a preheating furnace, vacuum evacuating a deposit chamber of a plasma enhanced chemical vapor deposition device (PECVD) to a pressure of 70×10⁻³ Pa, introducing residual nitrogen gas with a purity above 99.9%, and placing the glass substrate into the PECVD;

(4) introducing a mixture of gasses comprising SiH₄, CH₄ and B₂H₆ (volume ratio 1:1:0.01), performing glow discharge with a radio frequency of 30 MHz and a discharge power of 80 W, under a deposition temperature of 160-170° C. and a pressure of 60-65 Pa, and depositing a top cell P-film layer, a thickness of the deposited film being 100 Å;

(5) introducing a mixture of gasses comprising SiH₄ and H₂ (volume ratio 1:0.7) after vacuum evacuating the deposit chamber of the PECVD to a pressure of 7.0×10⁻³ Pa, performing glow discharge with a radio frequency of 60 MHz and a discharge power of 130 W, under a deposition temperature of 240-250° C. and a pressure of 65-70 Pa, and depositing a top cell I-film layer on the top cell P-film layer, a thickness of the deposited film being 600 Å;

(6) introducing a mixture of gasses comprising SiH₄ and PH₃ (volume ratio 1:0.01) after vacuum evacuating the deposit chamber of the PECVD to a pressure of 7.0×10⁻³ Pa, performing glow discharge with a radio frequency of 30 MHz and a discharge power of 150 W, under a deposition temperature of 260-265° C. and a pressure of 110-120 Pa, and depositing a top cell N-film layer on the top cell I-film layer, a thickness of the deposited film being 300 Å;

(7) introducing a mixture of gasses comprising SiH₄, B₂H₆ and CH₄ (volume ratio 1:0.8:0.012) after vacuum evacuating the deposit chamber of the PECVD to a pressure of 7.0×10⁻³ Pa, performing glow discharge with a radio frequency of 60 MHz and a discharge power of 80 W, under a deposition temperature of 160-170° C. and a pressure of 60-90 Pa, and depositing a bottom cell P-film layer on the top cell N-film layer, a thickness of the deposited film being 200 Å;

(8) introducing a mixture of gasses comprising SiH₄ and H₂ (volume ratio 1:1.3) after vacuum evacuating the deposit chamber of the PECVD to a pressure of 7.0×10⁻³ Pa, performing glow discharge with a radio frequency of 10 MHz and a discharge power of 190 W, under a deposition temperature of 190-200° C. and a pressure of 130 Pa, and depositing a bottom cell I-film layer on the bottom cell P-film layer, a thickness of the deposited film being 950 Å;

(9) introducing a mixture of gasses comprising SiH₄ and PH₃ (volume ratio 1:0.008) after vacuum evacuating the deposit chamber of the PECVD to a pressure of 7.0×10⁻³ Pa, and depositing a bottom cell N-film layer on the bottom cell I-film layer, a thickness of the deposited film being 300 Å;

(10) segmenting the dual P-I-N junction film layer on the glass substrate via laser ablation, so as to produce a series of electrodes;

(11) placing the glass substrate into the deposit chamber of the PECVD, and depositing back electrode film layer made of aluminum, a thickness of the film being 5000 Å;

(12) segmenting the back electrode film layer via laser ablation, so as to produce a series of back electrodes of the solar cell chip; and

(13) welding electrode wires of the positive electrode and the back electrode. As determined by testing, an open circuit voltage of the double-junction amorphous silicon solar cell chip is 40 V (DC), a generation power thereof is 30-35 W, a photoelectric conversion efficiency thereof is 6%, an attenuation rate thereof is 20%, and an output efficiency after conversion is 80%.

### Example 1-2

A technical process and working gas are the same as those in example 1-1.

(1) choosing a glass substrate containing an aluminum doped zinc oxide layer of 8000 Å in thickness, and cleaning and rearranging the glass substrate; in this embodiment, the glass substrate is a PV-TCO made by AFG Industries, Inc., USA, with a length of 1830 mm, a width of 615 mm, a height of 3 mm, a transmittance of 98%, and iron content of 70 ppm;

(2) segmenting film layers on the glass substrate via laser ablation, and producing a cathode of the solar cell chip;

(3) heating the glass substrate to 180° C. via a preheating furnace, vacuum evacuating a deposit chamber of a plasma enhanced chemical vapor deposition device (PECVD) to a pressure of 5.0×10⁻³ Pa, and introducing residual nitrogen gas with a purity above 99.8%;

(4) introducing a mixture of gasses comprising SiH₄, CH₄ and B₂H₆ (volume ratio 1:0.8:0.012) after vacuum evacuating the deposit chamber of the PECVD to a pressure of 50×10⁻³ Pa, performing glow discharge with a radio frequency of 60 MHz and a discharge power of 200 W, under a deposition temperature of 290° C. and a pressure of 180 Pa, a thickness of the deposited film being 200 Å;

(5) introducing a mixture of gasses comprising SiH₄ and H₂ (volume ratio 1:1.3) after vacuum evacuating the deposit chamber of the PECVD to 5.0×10⁻³ Pa, performing glow discharge with a radio frequency of 30 MHz and a discharge power of 200 W, under a deposition temperature of 295° C. and a pressure of 180 Pa, a thickness of the deposited film being 980 Å;

(6) introducing a mixture of gasses comprising SiH₄ and PH₃ (volume ratio 1:0.008) after vacuum evacuating the deposit chamber of the PECVD to a pressure of 5.0×10⁻³ Pa, performing glow discharge with a radio frequency of 60 MHz and a discharge power of 250 W, under a deposition temperature of 160-165° C. and a pressure of 180-200 Pa, and depositing a top cell N-film layer on a top cell I-film layer, a thickness of the deposited film being 500 Å;

(7) introducing a mixture of gasses comprising SiH₄, B₂H₆ and CH₄ (volume ratio 1:1.2:0.008) after vacuum evacuating the deposit chamber of the PECVD to a pressure of 5.0×10⁻³ Pa, performing glow discharge with a radio frequency of 10-15 MHz and a discharge power of 180-200 W, under a deposition temperature of 280-300° C. and a pressure of 160-180 Pa, a thickness of the deposited film being 80 Å;

(8) introducing a mixture of gasses comprising SiH₄ and H₂ (volume ratio 1:0.7) after vacuum evacuating the deposit chamber of the PECVD to a pressure of 5.0×10⁻³ Pa, performing glow discharge with a radio frequency of 55-60 MHz and a discharge power of 130-140 W, under a deposition temperature of 280-300° C. and a pressure of 160-180 Pa, and depositing a bottom cell I-film layer on a bottom cell P-film layer, a thickness of the deposited film being 210 Å;

(9) introducing a mixture of gasses comprising SiH₄ and PH₃ (volume ratio 1:0.012) after vacuum evacuating the deposit chamber of the PECVD to a pressure of 5.0×10⁻³ Pa, and depositing a bottom cell N-film layer on the bottom cell I-film layer, a thickness of the deposited film being 100 Å;

(10) segmenting the dual P-I-N junction film layer on the glass substrate via laser ablation, so as to produce a series of electrodes;

(11) placing the glass substrate into the deposit chamber of the PECVD, and depositing back electrode film layer made of aluminum, a thickness of the film being 8000 Å;

(12) segmenting the back electrode film layer via laser ablation, so as to produce a series of back electrodes of the solar cell chip; and

(13) welding electrode wires of the positive electrode and the back electrode. As determined by testing, an open circuit voltage of the double-junction amorphous silicon solar cell chip is approximately 52 V (DC), a generation power thereof is 50-55 W, a photoelectric conversion efficiency thereof is 5.5%, an attenuation rate thereof is 23%, and an output efficiency after conversion is 80%.

### Example 1-3

A technical process and working gas are the same as those in example 1-1.

(1) choosing a glass substrate containing a tin oxide layer of 6500 Å in thickness, and cleaning and rearranging the glass substrate, in this embodiment, the glass substrate is a PV-TCO made by AFG Industries, Inc., USA, with a length of 1245 mm, a width of 635 mm, a height of 3.2 mm, a transmittance of 95%, and iron content of 80 ppm;

(2) segmenting film layers on the glass substrate via laser ablation, and producing a cathode of the solar cell chip;

(3) heating the glass substrate to 230° C. via a preheating furnace, vacuum evacuating a deposit chamber of a plasma enhanced chemical vapor deposition device (PECVD) to a pressure of 8.0×10⁻³ Pa, and introducing residual nitrogen gas with a purity above 99.5%;

(4) introducing a mixture of gasses comprising SiH₄, CH₄ and B₂H₆ (volume ratio 1:1.2:0.008) after vacuum evacuating the deposit chamber of the PECVD to a pressure of 9.0×10⁻³ Pa, performing glow discharge with a radio frequency of 10 MHz and a discharge power of 120 W, under a deposition temperature of 260° C. and a pressure of 120 Pa, a thickness of the deposited film being 80 Å;

(5) introducing a mixture of gasses comprising SiH₄ and H₂ (volume ratio 1:1) after vacuum evacuating the deposit chamber of the PECVD to a pressure of 8.0×10⁻³ Pa, performing glow discharge with a radio frequency of 10 MHz and a discharge power of 180 W, under a deposition temperature of 250° C. and a pressure of 180 Pa, a thickness of the deposited film being 200 Å;

(6) introducing a mixture of gasses comprising SiH₄ and PH₃ (volume ratio 1:0.012) after vacuum evacuating the deposit chamber of the PECVD to a pressure of 8.0×10⁻³ Pa, performing glow discharge with a radio frequency of 15 MHz and a discharge power of 200 W, under a deposition temperature of 290-300° C. and a pressure of 80-100 Pa, and depositing a top cell N-film layer on a top cell I-film layer, a thickness of the deposited film being 100 Å;

(7) introducing a mixture of gasses comprising SiH₄, B₂H₆ and CH₄ (volume ratio 1:1:0.1) after vacuum evacuating the deposit chamber of the PECVD to a pressure of 8.0×10⁻³ Pa, performing glow discharge with a radio frequency of 45 MHz and a discharge power of 150 W, under a deposition temperature of 200-210° C. and a pressure of 100 Pa, a thickness of the deposited film being 150 Å;

(8) introducing a mixture of gasses comprising SiH₄, GeH₄ and H₂ (volume ratio 1:0.4:0.7) after vacuum evacuating the deposit chamber of the PECVD to a pressure of 9.0×10⁻³ Pa, performing glow discharge with a radio frequency of 50-60 MHz and a discharge power of 190-200 W, under a deposition temperature of 280-300° C. and a pressure of 160-180 Pa, and depositing a bottom cell I-film layer on a bottom cell P-film layer, a thickness of the deposited film being 1000 Å;

(9) introducing a mixture of gasses comprising SiH₄ and PH₃ (volume ratio 1:0.01) after vacuum evacuating the deposit chamber of the PECVD to a pressure of 8.0×10⁻³ Pa, and depositing a bottom cell N-film layer on the bottom cell I-film layer, a thickness of the deposited film being 500 Å;

(10) segmenting the dual P-I-N junction film layer on the glass substrate via laser ablation, so as to produce a series of electrodes;

(11) placing the glass substrate into the deposit chamber of the PECVD, and depositing back electrode film layer made of aluminum, the thickness of the film being 7000 Å;

(12) segmenting the back electrode film layer via laser ablation, so as to produce a series of back electrodes of the solar cell chip; and

(13) welding electrode wires of the positive electrode and the back electrode.

As determined by testing, an open circuit voltage of the double-junction amorphous silicon solar cell chip is approximately 48 V (DC), a generation power thereof is 35-45 W, a photoelectric conversion efficiency thereof is 7%, an attenuation rate thereof is 30%, and an output efficiency after conversion is 80%.

### Example 1-4

A technical process and working gas are the same as those in example 1-1.

(1) choosing a glass substrate containing an indium tin oxide layer of 7500 Å in thickness, and cleaning and rearranging the glass substrate, in this embodiment, the glass substrate is a PV-TCO made by AFG Industries, Inc., USA, with a length of 1230 mm, a width of 480 mm, a height of 3.8 mm, a transmittance of 92%, and iron content of 60 ppm;

(2) segmenting film layers on the glass substrate via laser ablation, and producing a cathode of the solar cell chip;

(3) heating the glass substrate to 200° C. via a preheating furnace, vacuum evacuating a deposit chamber of a plasma enhanced chemical vapor deposition device (PECVD) to a pressure of 7.0×10⁻³ Pa, and introducing residual nitrogen gas with a purity above 99.2%;

(4) introducing a mixture of gasses comprising SiH₄, CH₄ and B₂H₆ (volume ratio 1:1:0.008) after vacuum evacuating the deposit chamber of the PECVD to a pressure of 6.0×10⁻³ Pa, performing glow discharge with a radio frequency of 35 MHz and a discharge power of 100 W, under a deposition temperature of 200° C. and a pressure of 100 Pa, a thickness of the deposited film being 110 Å;

(5) Introducing a mixture of gasses comprising SiH₄ and H₂ (volume ratio 1:1.1) after vacuum evacuating the deposit chamber of the PECVD to a pressure of 6.0×10⁻³ Pa, performing glow discharge with a radio frequency of 20 MHz and a discharge power of 160 W, under a deposition temperature of 230° C. and a pressure of 150 Pa, a thickness of the deposited film being 400 Å;

(6) introducing a mixture of gasses comprising SiH₄ and PH₃ (volume ratio 1:0.01) after vacuum evacuating the deposit chamber of the PECVD to a pressure of 6.0×10⁻³ Pa, performing glow discharge with a radio frequency of 15 MHz and a discharge power of 200 W, under a deposition temperature of 160-165° C. and a pressure of 150-160 Pa, and depositing a top cell N-film layer on a top cell I-film layer, a thickness of the deposited film being 150 Å;

(7) introducing a mixture of gasses comprising SiH₄, PH₃ and CH₄ (volume ratio 1:1:0.1) after vacuum evacuating the deposit chamber of the PECVD to a pressure of 7.0×10⁻³ Pa, performing glow discharge with a radio frequency of 45 MHz and a discharge power of 150 W, under a deposition temperature of 280-290° C. and a pressure of 130 Pa, a thickness of the deposited film being 140 Å;

(8) introducing a mixture of gasses comprising SiH₄, GeH₄ and H₂ (volume ratio 1:0.6:1.3) after vacuum evacuating the deposit chamber of the PECVD to a pressure of 8.8×10⁻³ Pa, performing glow discharge with a radio frequency of 10-15 MHz and a discharge power of 130-140 W, under a deposition temperature of 160-180° C. and a pressure of 60-70 Pa, and depositing a bottom cell I-film layer on a bottom cell P-film layer, a thickness of the deposited film being 220 Å;

(9) introducing a mixture of gasses comprising SiH₄ and PH₃ (volume ratio 1:0.01) after vacuum evacuating the deposit chamber of the PECVD to a pressure of 5.0×10⁻³ Pa, and depositing a bottom cell N-film layer on the bottom cell I-film layer, a thickness of the deposited film being 500 Å;

(10) segmenting the dual P-I-N junction film layer on the glass substrate via laser ablation, so as to produce a series of electrodes;

(11) placing the glass substrate into the deposit chamber of the PECVD, and depositing back electrode film layer made of aluminum, a thickness of the film being 6000 Å;

(12) segmenting the back electrode film layer via laser ablation, so as to produce a series of back electrodes of the solar cell chip; and

(13) welding electrode wires of the positive electrode and the back electrode. As determined by testing, an open circuit voltage of the double-junction amorphous silicon solar cell chip is approximately 42 V (DC), a generation power thereof is 35-40 W, a photoelectric conversion efficiency thereof is 6.7%, an attenuation rate thereof is 24%, and an output efficiency after conversion is 75%.

### Embodiment 2

### Encapsulation of the Photovoltaic Curtain Wall Plate

### Example 2-1

### Encapsulation of a B-Type Double-Junction Amorphous Silicon Solar Cell Curtain Wall

An EVA glue file 7 (with a length of 915 mm, a width of 480 mm and a thickness of 3.2 mm) was disposed on the solar cell chip 5 with the same size. A toughened glass 6 with a thickness of 6 mm was aligned with and placed on the EVA glue file 7 and the solar cell chip 5. During this process, electrode wires on the solar cell chip 5 were passed through a hole on the EVA glue file 7 and the toughened glass 6, and then all the above-mentioned components were heated in a vacuum state of 10 Pa with a temperature of 120° C., bonded together at 0.5 atmospheric pressure, inlayed with a frame 15, connected with a corner connection 25, fixed with a screw 22, and sealed with silicone sealant 26. Finally, a terminal box 8 was attached to the toughened glass 6 via silicone sealant 26, and a lead 9 was connected to the terminal box 8.

In this embodiment, the dimension of the photovoltaic curtain wall plate 1 was 925 mm (length)×490 mm (width)×38 mm (height), the open circuit voltage thereof was 40 V (DC), and the generated power was 30-35 W.

### Example 2-2

### Encapsulation of an A-Type Double-Junction Amorphous Silicon Solar Cell Curtain Wall

An EVA glue file 7 (with a length of 1245 mm, a width of 635 mm, and a thickness of 3.2 mm) was disposed on the solar cell chip 5 with the same size. A toughened glass 6 with a thickness of 6 mm was aligned with and placed on the EVA glue file 7 and the solar cell chip 5. During this process, electrode wires on the solar cell chip 5 were passed through a hole on the EVA glue file 7 and the toughened glass 6, and then all the above-mentioned components are heated in a vacuum state of 50 Pa with a temperature of 120° C., bonded together at 0.5 atmospheric pressure, inlayed with a frame 15, connected with the corner connection 25, fixed with the screw 22, and sealed with silicone sealant 26. Finally, a pair of terminal boxes 8 was attached to the toughened glass 6 via silicone sealant 26, and a lead 9 was connected to each of the terminal box 8.

In this embodiment, the dimension of the photovoltaic curtain wall plate 1 is 1255 mm (length) X 645 mm (width) X 38 mm (height), an open circuit voltage thereof is 48 V (DC), and a generation power is 40 W.

### Example 2-3

### Encapsulation of a B-Type Double-Junction Amorphous Silicon Solar Cell Curtain Wall

An EVA glue file 7 (with a length of 1245 mm, a width of 635 mm and a thickness of 3.2 mm) was disposed on the solar cell chip 5 with the same size. A toughened glass 6 with a thickness of 6 mm was aligned with and placed on the EVA glue file 7 and the solar cell chip 5. During this process, electrode wires on the solar cell chip 5 were passed through a hole on the EVA glue file 7 and the toughened glass 6. Then, all the above-mentioned components were heated in a vacuum state of 10 Pa at a temperature of 150° C., bonded together at 0.8 atmospheric pressure, inlayed with the frame 15, connected with the corner connection 25, fixed with the screw 22, and sealed with silicone sealant 26. Finally, a pair of terminal boxes 8 was attached to the toughened glass 6 via silicone sealant 26, and a lead 9 was connected to each of the terminal box 8.

In this embodiment, a dimension of the photovoltaic curtain wall plate 1 is 1255 mm (length)×645 mm (width)×38 mm (height), an open circuit voltage thereof is 48 V (DC), and a generation power is 40 W.

### Embodiment 3

### Application of an Integrated Amorphous Silicon Double-Junction Solar Cell Curtain Wall

### Example 3-1

### Standalone Power Generation of an Integrated Amorphous Silicon Double-Junction Solar Cell Curtain Wall

Referring to FIG. 13, nine B-type double-junction amorphous silicon solar cell curtain wall plates are serially connected to form a group (the open circuit voltage of the group is 360 V (DC), and a total generation power thereof is approximately 270 W), and 20 groups are connected in parallel. The open circuit voltage of the photovoltaic curtain wall plate array is 360V (DC), and a total generation power thereof is approximately 5400 W.

In this embodiment, the photoelectric conversion efficiency of the solar cell chip is approximately 7%, an attenuation rate is 30%, the output efficiency after conversion is 80%, and it is capable of outputting an AC of 220 V, and providing an electric power of less than 4 kW.

### Example 3-2

### Wall Decoration of Buildings and Interconnected Power Generation

Referring to FIG. 14, a photovoltaic curtain wall plate array made of a plurality of A-type double-junction amorphous silicon solar cell curtain wall plates is shown. In detail, seven A-type double-junction amorphous silicon solar cell curtain wall plates are serially connected to form a group (an open circuit voltage of the group is 360V (DC), and a total generation power thereof is approximately 280 W), and 108 groups are parallel connected. An open circuit voltage of the photovoltaic curtain wall plate array is 350 V (DC), and a total generation power thereof is approximately 30.24 kW.

In this embodiment, the photoelectric conversion efficiency of the solar cell chip is approximately 6%, an attenuation rate is 28%, the output efficiency after conversion is 80%, and is capable of outputting an AC of 220 V, and providing an electric power less than 24 kW.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

What is claimed is:

1. An integrated amorphous silicon double-junction solar cell curtain wall, comprising:
a plurality of photovoltaic curtain wall plates; and
an electric control unit having a controller; wherein,
said photovoltaic curtain wall plate is encapsulated by a double-junction amorphous silicon solar cell chip with a glass substrate, a glass plate, a glue film, a junction box, a lead, and a frame;
the plurality of photovoltaic curtain wall plates are connected to form a frame-type integrated wall;
an electric output of said photovoltaic curtain wall plate is connected to a controller of an electric control unit; and
said controller is connected to a power distributing cabinet is connected to a power distributing cabinet via a network inverter.

2. The integrated amorphous silicon double-junction solar cell curtain wall of claim 1, wherein
said glass substrate comprises one of tin oxide, indium tin oxide, or aluminum doped zinc oxide;
a tandem solar cell film layer and a back electrode are disposed on said glass substrate;
said tandem solar cell film layer comprises a top cell film layer and a bottom cell film layer;
each of the top cell film layer and the bottom cell film layer comprises a P-layer, an I-layer, and an N-layer;
an I-layer of the top cell film layer is amorphous silicon; and
an I-layer of the bottom cell film layer is amorphous silicon or amorphous germanium-silicon.

3. The integrated amorphous silicon double-junction solar cell curtain wall of claim 1, wherein a lightning protection system is disposed between said output of said photovoltaic curtain wall plate and said controller.

4. The integrated amorphous silicon double-junction solar cell curtain wall of claim 1, wherein said power distributing cabinet is connected to an urban power network via an input electric meter and an output electric meter.

5. A method for manufacturing an integrated amorphous silicon double-junction solar cell curtain wall of claim 1, comprising
encapsulating a photovoltaic curtain wall plate;
connecting a plurality of photovoltaic curtain wall plates to form an integrated wall via a frame-type structure; and
encapsulating an electric control unit;
wherein a process of manufacturing a double-junction amorphous silicon solar cell chip comprises:
(1) choosing a glass substrate containing a tin oxide layer of 5000 Å-8000 Å in thickness, and cleaning and rearranging said glass substrate;
(2) segmenting film layers on said glass substrate via laser ablation, and producing a cathode of said solar cell chip;
(3) accommodating said glass substrate with a fixture deposited with P, I and N-film layers, heating said glass substrate to 180° C.-250° C. via a preheating furnace, vacuum evacuating a deposit chamber of a plasma enhanced chemical vapor deposition device (PECVD) to a pressure of between 5.0×10⁻³ Pa and 9.0×10⁻³ Pa, introducing residual nitrogen gas with a purity above 99%, and placing said glass substrate into said PECVD;
(4) introducing a mixture of gasses comprising SiH₄, CH₄ and B₂H₆ in a volume ratio of 1:0.8-1.2:0.008-0.012 after vacuum evacuating the deposit chamber of the PECVD to a pressure of between 5.0×10⁻³ Pa and 9.0×10⁻³, performing glow discharge with a radio frequency of 10-60 MHz and a discharge power of 80 W-200 W, under a deposition temperature of 160-300° C. and a pressure of 40-1000 Pa, and depositing a top cell P-film layer, a thickness of the deposited film being 80 Å-200 Å;
(5) introducing a mixture of gasses comprising SiH₄ and H₂ at a volume ratio of 1: 1-10 after vacuum evacuating the depo sit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a top cell I-film layer on the top cell P-film layer, a thickness of the deposited film being 500 Å-1000 Å;
(6) introducing a mixture of gasses comprising SiH₄ and PH₃ at a volume ratio of 1:0.008-0.012 after vacuum evacuating the deposit chamber of the PECVD to a pressure of between 5.0×10⁻³ Pa and 9.0×10⁻³, performing glow discharge with a radio frequency of 10-60 MHz and a discharge power of 150 W-250 W, under a deposition temperature of 160-300° C. and a pressure of 40-1000 Pa, and depositing a top cell N-film layer on the top cell I-film layer, a thickness of the deposited film being 100 Å-300 Å; and
(7) introducing a mixture of gasses comprising SiH₄, CH₄ and B₂H₆ at a volume ratio of 1:0.8-1.2:0.008-0.012 after vacuum evacuating the deposit chamber of the PECVD to 5.0×10⁻³ Pa-9.0×10⁻³, performing glow discharge with a radio frequency of 10-60 MHz and a discharge power of 80 W-200 W, under a deposition temperature of 160-300° C. and a pressure of 40-1000 Pa, and depositing a bottom cell P-film layer on the top cell N-film layer, a thickness of the deposited film being 80 Å-200 Å.
(8) A. introducing a mixture of gasses comprising SiH₄ and H₂ at a volume ratio of 1:0.7-1.3 after vacuum evacuating the deposit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a top cell I-film layer on the top cell P-film layer, a thickness of the deposited film being 200 Å-1000 Å.
B. introducing a mixture of gasses comprising SiH₄, GeH₄ and H₂ at a volume ratio of 1:0.4-0.6:1-5 after vacuum evacuating the deposit chamber of the PECVD to a pressure of between 5.0×10⁻³ Pa and 9.0×10⁻³, performing glow discharge with a radio frequency of 10-60 MHz and a discharge power of 130 W-200 W, under a deposition temperature of 160-300° C. and a pressure of 40-1000 Pa, and depositing a bottom cell amorphous germanium silicon I-film layer on the bottom cell P-film layer, a thickness of the deposited film being 1000 Å-2500 Å.
9) introducing a mixture of gasses comprising SiH₄ and PH₃ at a volume ratio of 1:0.008-0.012 after vacuum evacuating the deposit chamber of the PECVD to a pressure of between 5.0×10⁻³ Pa and 9.0×10⁻³, performing glow discharge with a radio frequency of 10-60 MHz and a discharge power of 150 W-250 W, under a deposition temperature of 160-300° C. and a pressure of 80-200 Pa, and depositing a bottom cell N-film layer on the bottom cell I-film layer, so as to form a dual P-I-N junction film layer, a thickness of the deposited film being 300 Å-500 Å;
(10) segmenting said dual P-I-N junction film layer on said glass substrate via laser ablation, so as to produce a series of electrodes;
(11) placing said glass substrate into said deposit chamber of said PECVD, and depositing back electrode film layer made of aluminum, a thickness of the film being 5000 Å-8000 Å;
(12) segmenting said back electrode film layer via laser ablation, so as to produce a series of back electrodes of said solar cell chip; and
(13) welding electrode wires of the positive electrode and the back electrode.

6. The method of claim 5, wherein a transmittance of said glass substrate is 90%-98%, and an iron content of said glass substrate is 60 ppm-80 ppm.

7. The integrated amorphous silicon double-junction solar cell curtain wall of claim 1, wherein said integrated amorphous silicon double-junction solar cell curtain wall is usable for solar power generation and wall decoration of buildings.
